(19) United States
(12) Patent Application Publication
(10) Pub. No.: US 2025/0347030 A1
(43) Pub. Date: Nov. 13, 2025

(54) METHOD FOR RECYCLING RARE-EARTH BARIUM COPPER OXIDE (REBCO) SEED CRYSTALS TO GROW SUPERCONDUCTING BULK

(71) Applicant: SOUTHWEST JIAOTONG UNIVERSITY, Chengdu (CN)

(72) Inventors: Zigang DENG, Chengdu (CN); Xiwen ZHANG, Chengdu (CN); Tingting LI, Chengdu (CN); Yunrui SONG, Chengdu (CN); Rong TANG, Chengdu (CN)

(21) Appl. No.: 19/277,177

(22) Filed: Jul. 22, 2025

Related U.S. Application Data
(63) Continuation of application No. PCT/CN2024/144488, filed on Dec. 31, 2024.

(30) Foreign Application Priority Data
Mar. 18, 2024 (CN) 202410307195.8

(51) Int. Cl. C30B 29/22; C30B 11/14; C30B 33/00

(52) U.S. Cl. CPC C30B 29/225; C30B 11/14; C30B 33/00

(57) ABSTRACT

A method for recycling rare-earth barium copper oxide (REBCO) bulk seed crystals to grow a superconducting bulk is provided, in which a first precursor and a first buffer layer are prepared, and based on a top-seeded melt-texture growth method, an original REBCO superconducting bulk is obtained, which is cleaved to obtain a recycled seed crystal; the recycled seed crystal is subjected to grinding and polishing; a second precursor and a second buffer layer are prepared, and the recycled seed crystal is inserted between the second precursor and the second buffer layer; the precursor assembly is treated through the top-seeded melt-texture growth method to obtain a REBCO superconducting bulk grown from the recycled seed crystal.

### CROSS-REFERENCE TO RELATED APPLICATIONS

This application is a continuation of International Patent Application No. PCT/CN2024/144488, filed on Dec. 31, 2024, which claims the benefit of priority from Chinese Patent Application No. 202410307195.8, filed on Mar. 18, 2024. The content of the aforementioned application, including any intervening amendments thereto, is incorporated herein by reference in its entirety.

### TECHNICAL FIELD

This application relates to superconducting material recycling technologies, and more particularly to a method for recycling rare-earth barium copper oxide (REBCO) seed crystals to grow a superconducting bulk.

### BACKGROUND

The batch fabrication of superconducting bulks is mainly limited by cost control and quality control. The existing fabrication techniques of rare-earth barium copper oxide (REBCO) superconducting bulks struggle with complex process, long preparation cycle and poor yield rate, and a large number of failed samples are also produced in the batch fabrication process, which will cause a serious waste of the expensive light rare earth elements contained therein. Therefore, the development of recycling technologies for REBCO bulk materials has attracted considerable attention.

In the conventional processes, bulk seed crystals are usually stripped from a top of a grown sample and then discarded, regardless of the high cost and complex preparation process. Moreover, seed crystals may vary in the crystallinity, and thus different seed crystals may require different temperature programs to prepare bulk materials. At the same time, properties of the superconducting bulk materials induced by different seed crystals may also vary significantly, which increases trial-error cost and quality control cost of growing bulk materials. Therefore, in order to ensure that the superconducting properties of the samples are as consistent as possible to meet the requirements of batch preparation, and also to avoid the waste of expensive light rare earth element-containing bulk seed crystals to reduce the preparation cost of the REBCO bulk materials, it is urgently needed to develop a method for recycling REBCO bulk seed crystals.

### SUMMARY

In order to solve the above problems, this application provides a method for recycling rare-earth barium copper oxide (REBCO) bulk seed crystals to grow a superconducting bulk.

The technical solutions of this application are described as follows.

A method for recycling rare-earth barium copper oxide (REBCO) bulk seed crystals to grow a superconducting bulk is provided, comprising:
(S1) preparing a first precursor and a first buffer layer based on a preset REBCO superconducting bulk precursor preparation method and a preset REBCO superconducting bulk buffer layer preparation method;
(S2) based on a top-seeded melt-texture growth method, performing a heating treatment on an original REBCO seed crystal, the first precursor and the first buffer layer to obtain an original REBCO superconducting bulk;
(S3) performing cleavage on the original REBCO superconducting bulk along a preset cleavage plane to obtain a cleavage structure composed of the first buffer layer and the original REBCO seed crystal, and grinding and polishing the cleavage structure to obtain a recycled seed crystal;
(S4) preparing a second precursor and a second buffer layer; placing the recycled seed crystal on a center of a top of the second precursor; and coaxially inserting the second buffer layer between the recycled seed crystal and the second precursor to obtain a precursor assembly; and
(S5) based on the top-seeded melt-texture growth method, performing the heating treatment on the precursor assembly to obtain a REBCO superconducting bulk grown from the recycled seed crystal.

In an embodiment, step (S1) comprises:
mixing RE₂O₃, BaCO₃ and CuO in a molar ratio of 1:4:6 to obtain an original RE123 powder; and mixing RE₂O₃, BaCO₃ and CuO in a molar ratio of 1:1:1 to obtain an original RE211 powder;
performing solid-phase sintering on the original RE123 powder and the original RE211 powder to obtain a purified RE123 powder and a purified RE211 powder, respectively;
mixing the purified RE123 powder and the purified RE211 powder in a molar ratio of 1:0.35 to obtain a precursor powder; and mixing the precursor powder with a CeO₂ powder to obtain a precursor pellet, wherein the CeO₂ powder is 1% by weight of the precursor powder;
pressing the precursor pellet in a first mold to obtain the first precursor; and
pressing the purified RE123 powder, the purified RE211 powder and the CeO₂ powder in a preset ratio in a second mold to obtain the first buffer layer.

In an embodiment, the step of performing solid-phase sintering on the original RE123 powder and the original RE211 powder comprises:
sintering the original RE123 powder at 920° C. in an air atmosphere for 48 h to obtain a sintered RE123 powder, and sintering the original RE211 powder at 930° C. in an air atmosphere for 48 h to obtain a sintered RE211 powder; and
performing grinding and sintering on the sintered RE123 powder three times to obtained the purified RE123 powder, and performing grinding and sintering on the sintered RE211 powder three times to obtain the purified RE211 powder.

In an embodiment, the step of pressing the purified RE123 powder, the purified RE211 powder and the CeO₂ powder in the preset ratio in the second mold to obtain the first buffer layer comprises:
mixing the purified RE123 powder and the purified RE211 powder in a molar ratio of 5:2, followed by mixing with the CeO₂ powder to obtain a second mixed powder, wherein the CeO₂ powder is 1% by weight of a mixture of the purified RE123 powder and the purified RE211 powder; and
placing the second mixed powder in the second mold followed by pressing to obtain the first buffer layer with a cylindrical shape, wherein the second mold is a cylindrical mold with a diameter of 6 mm.

In an embodiment, step (S2) comprises:
inserting the first buffer layer between the original REBCO seed crystal and the first precursor to form a coaxially composite structure from top to bottom; and
placing the composite structure on an aluminum oxide ceramic plate, followed by transfer to a furnace in an air atmosphere for texture growth in the air atmosphere to obtain the REBCO superconducting bulk induced by the original REBCO seed crystal.

In an embodiment, the step of inserting the first buffer layer between the original REBCO seed crystal and the first precursor to form a composite structure comprises:
selecting a single REBCO seed crystal single grain with a smooth cross section and a size of 3 mm×3 mm×3 mm as the original REBCO seed crystal; and polishing an ab plane of the original REBCO seed crystal to obtain a polished REBCO seed crystal; and
placing the original REBCO seed crystal between the first buffer layer and the first precursor with a central axis of the original REBCO seed crystal perpendicular to ground aligned with a central axis of the first buffer layer and a central axis of the first precursor, so as to obtain the composite structure.

In an embodiment, the step of placing the composite structure on the aluminum oxide ceramic plate, followed by transfer to the furnace in the air atmosphere for texture growth comprises:
heating the furnace for 1 h to allow a temperature in the furnace to increase from room temperature to 900° C., keeping the furnace at 900° C. for 3 h, heating the furnace for 1 h to allow the temperature to increase from 900° C. to 1055° C., and keeping the furnace at 1055° C. for 1 h;
cooling the furnace to 1005° C. within 30 min; and cooling the furnace at a cooling rate of 0.2K/h-0.4K/h to allow the original REBCO seed crystal to induce the texture growth of the first precursor for 100 h; and
after the texture growth, cooling the furnace to the room temperature within 3 h.

In an embodiment, a rare earth element in the REBCO bulk seed crystal is selected from the group consisting of yttrium (Y), gadolinium (Gd), samarium (Sm) and neodymium (Nd).

In an embodiment, the step of performing cleavage on the original REBCO superconducting bulk along the preset cleavage plane comprises:
performing cleavage on the original REBCO superconducting bulk along a crystal ab plane through a cutting tool to obtain a REBCO bulk seed crystal with the first buffer layer with a thickness of 0.5 mm, wherein the crystal ab plane is a layering cross section of a layered structure in the original REBCO superconducting bulk; and
polishing a cleavage plane of the REBCO bulk seed crystal through a 1000-mesh sandpaper to obtain the recycled seed crystal.

In an embodiment, a weight ratio of powders for preparing the second buffer layer to powders for preparing the first buffer layer is 1:2.

In an embodiment, after obtaining the REBCO superconducting bulk grown from the recycled seed crystal, the method further comprises:
recycling a seed crystal from the REBCO superconducting bulk grown from the recycled seed crystal, and performing grinding and polishing on the REBCO superconducting bulk grown from the recycled seed crystal and the original REBCO superconducting bulk to obtain two completely-grown bulks;
annealing the two completely-grown bulks in the furnace in a flowing oxygen atmosphere at 450° C. for 200 h to obtain two annealed REBCO superconducting bulks; and
performing a magnetic levitation force test on the two annealed REBCO superconducting bulks to obtain test results.

The present disclosure has the following beneficial effects.

The method of the present disclosure can achieve a lose-free seed crystal recycling process, and bulks with good morphology can be successfully grown at each time, which can achieve as many seed crystal recycling times as possible. Through the present disclosure, REBCO superconducting bulks can be repeatedly prepared from two aspects of growth morphology and magnetic levitation force performance. In addition, the present disclosure ensures a relative position of the seed crystals therebetween by taking advantage of characteristics that solid solutions can maintain its own shape in a molten state, which reliably achieves an effect of repeatedly guiding the growth of the precursor underneath.

Other features and advantages of the present disclosure will be described below, and part of them will become obvious from the specification or are understood through the embodiments. Objects and other advantages of the present disclosure can be realized and obtained from structures specifically pointed out in the specification, claims and accompanying drawings.

### BRIEF DESCRIPTION OF THE DRAWINGS

In order to illustrate the technical solutions of this application or the prior art more clearly, the accompanying drawings required in the description of embodiments or the prior art will be briefly introduced below. It is obvious that the following accompanying drawings only show some embodiments of this application, and for those of ordinary skill in the art, other relevant accompanying drawings can also be obtained according to these drawings without making creative effort.

FIG. 1 is a flow chart of a method for recycling rare-earth barium copper mixed oxide (REBCO) bulk seed crystals to grow a superconducting bulk according to an embodiment of the present disclosure.

FIG. 2 shows test results of a magnetic levitation force test on the REBCO bulk seed crystals.

### DETAILED DESCRIPTION OF EMBODIMENTS

To make the above object, features and advantages of the present disclosure more clearly, the present disclosure will be further described below with reference to the accompanying drawings. It is obvious that described herein are only some embodiments of the present disclosure, rather than all embodiments. Components of the embodiments of the present disclosure which are usually described and shown in the accompanying drawings herein, can be arranged and designed in various configurations. Therefore, described below are embodiments of the present disclosure, which are not intended to limit the disclosure, and are only to show selected embodiments of the present disclosure. Based on the embodiments of the present disclosure other embodiments obtained by those of ordinary skill in the art without making creative effort shall fall within the scope of the present disclosure.

It should be noted that similar labels and letters represent similar items in the accompanying drawings, therefore, once an item is defined in one accompanying drawing, it does not need to be further defined and explained in subsequent accompanying drawings. In addition, the terms “first” and “second” are only used for distinguishment rather than indicating or implying the relative importance or implicitly specifying the number of technical features indicated.

### Embodiment 1

In this embodiment, a method for continuous recycling of rare-earth barium copper mixed oxide (REBCO) bulk seed crystals to grow a superconducting bulk is provided.

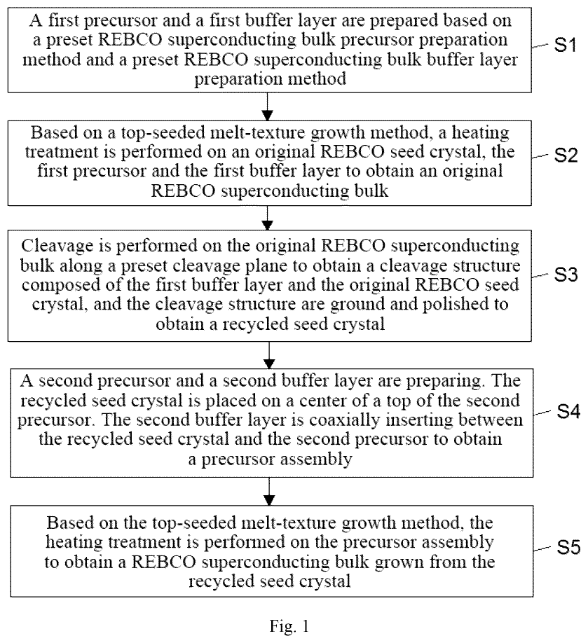

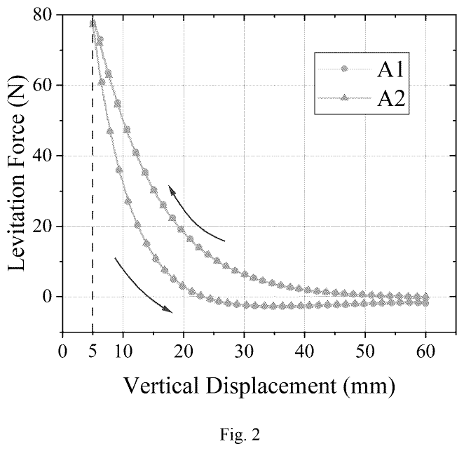

Steps (S1)-(S5) are shown in FIGS. 1-2.
(S1) A first precursor and a first buffer layer are prepared based on a preset REBCO superconducting bulk precursor preparation method of precursors of REBCO superconducting bulks and a preset REBCO superconducting bulk buffer layer preparation method of buffer layers.

It can be understood that step (S1) provides precursors and buffer layers with good crystallinity and density, which provides ideal substrates and backing materials for subsequent growth of superconductors. It is conducive to improving crystallization quality and performance of superconductor materials, thereby enhancing the performance and stability of whole superconducting bulks. Step (S1) includes steps (S11)-(S15).
(S11) RE₂O₃, BaCO₃ and CuO are mixed in a molar ratio of 1:4:6 to obtain an original RE123 powder. RE₂O₃, BaCO₃ and CuO are mixed in a molar ratio of 1:1:1 to obtain an original RE211 powder.
(S12) Solid-phase sintering is performed on the original RE123 powder and the original RE211 powder to obtain a purified RE123 powder and a purified RE211 powder, respectively.

It can be understood that step (S12) includes steps (S121)-(S122).
(S121) Sintering is performed on the original RE123 powder at 920° C. in an air atmosphere for 48 h to obtain a sintered RE123 powder, and sintering is performed on the original RE211 powder at 930° C. in an air atmosphere for 48 h to obtain a sintered RE123 powder and a sintered RE211 powder.
(S122) Grinding and sintering are performed on the sintered RE123 powder three times to obtained the purified RE123 powder, and grinding and sintering are performed on the sintered RE211 powder three times to obtain the purified RE211 powder.

It can be understood that in this step, original powders are sintered for a long time under specific temperature and environmental conditions to promote bonding between powder particles and growth of crystals to obtain the sintered RE123 powder and the sintered RE211 powder. Through sintering and grinding, purity and crystal structure of powders are improved, which provides high-quality raw materials for the subsequent preparation process of superconductors.
(S13) The purified RE123 powder and the purified RE211 powder are mixed in a molar ratio of 1:0.35 to obtain a precursor powder, and then the precursor powder is mixed with a CeO₂ powder to obtain a precursor pellet, where the CeO₂ powder is 1% by weight of the precursor powder.
(S14) The precursor pellet is pressed in a first mold to obtain the first precursor.
(S15) The purified RE123 powder, the purified RE211 powder and the CeO₂ powder are pressed in a preset ratio in a second mold to obtain the first buffer layer.

It can be understood that the step (S15) includes steps (S151)-(S152).
(S151) The purified RE123 powder and the purified RE211 powder are mixed in a molar ratio of 5:2, followed by mixing with the CeO₂ powder to obtain a second mixed powder, where the CeO₂ powder is 1% by weight of a mixture of the purified RE123 powder and the purified RE211 powder.
(S152) The second mixed powder is placed in the second mold followed by pressing to obtain the first buffer layer with a cylindrical shape, where the second mold is a cylindrical mold with a diameter of 6 mm.

It can be understood that above steps adopt solid-phase sintering and powder metallurgy, through precisely controlling molar ratios of original materials and process conditions, precursor pellets with required components and required structures are prepared to obtain the first precursor and the first buffer layer through pressing. In these steps, through precisely controlling molar ratios of original materials and process conditions, precursor pellets with required components and required structures are prepared to obtain the first precursor and the first buffer layer through pressing, which provides good basic materials and supporting structures for subsequent preparation process of superconductors.
(S2) Based on a top-seeded melt-texture growth method, a heating treatment is performed on an original REBCO seed crystal, the first precursor and the first buffer layer to obtain an original REBCO superconducting bulk.

It can be understood that guiding effect of a top seed crystal, a single crystal superconducting layer is grown on the top seed crystal through texture growth to form the original REBCO superconducting bulk, which can effectively control the growth quality and thickness of the superconducting layer, and improve the crystallization performance and uniformity of the material. Step (S2) includes steps (S21)-(S22).
(S21) The first buffer layer is inserted between the original REBCO seed crystal and the first precursor to form a coaxially composite structure from top to bottom.

It can be understood that step (S21) includes steps (S211)-(S212).
(S211) A single REBCO seed crystal single grain with a smooth cross section and a size of 3 mm×3 mm×3 mm is selected as the original REBCO seed crystal. An ab plane of the original REBCO seed crystal is polished to obtain a polished REBCO seed crystal.
(S212) The original REBCO seed crystal is placed between the first buffer layer and the first precursor with a central axis of the original REBCO seed crystal perpendicular to ground aligned with a central axis of the first buffer layer and a central axis of the first precursor, so as to obtain the composite structure.

It can be understood that the polishing treatment is to eliminate possible surface defects and roughness, so as to ensure that the original REBCO seed crystal can be closely combined with other components in the subsequent precursor assembly and growth process and provide a good growth surface. Through polishing, surface unevenness of the original REBCO seed crystal can be reduced, and crystal orientation can be further ensured, so as to improve the uniformity and stability during the growth process. The surface treatment of the original REBCO seed crystal together with the coaxially composite structure lay a foundation for the subsequent texture growth process. The smooth surface after treatment is conducive to the crystal growth and quality improvement during the growth process, while the coaxially composite structure ensures the tight combination and stability between each component, which is beneficial to the progress and control of the growth process.
(S22) The composite structure is placed on the aluminum oxide ceramic plate, followed by transfer to a furnace in an air atmosphere for texture growth in the air atmosphere to obtain an original yttrium barium copper oxide (YBCO) superconducting bulk induced by the original REBCO seed crystal (the original REBCO superconducting bulk induced by the original REBCO seed crystal).

It can be understood that in this step, the YBCO superconducting bulk is induced by the original REBCO seed crystal through the texture growth, so as to obtain the REBCO superconducting bulk with excellent superconducting properties. In such way, the crystal orientation and superconducting properties of the superconductor can be controlled during the preparation process, so as to enhance application value of the material. In this step, step (S22) includes steps (S221)-(S223).
(S221) The furnace for 1 h is heated to allow a temperature in the furnace to increase from room temperature to 900° C., the furnace is kept at 900° C. for 3 h, the furnace is heated for 1 h to allow the temperature to increase from 900° C. to 1055° C., and the furnace at 1055° C. is kept for 1 h.
(S222) The furnace is cooled to 1005° C. within 30 min. The furnace is cooled at a cooling rate of 0.2K/h-0.4K/h to allow the original REBCO seed crystal to induce the texture growth of the first precursor for 100 h.
(S223) After the texture growth, the furnace is cooled to the room temperature within 3 h.

It can be understood that the original REBCO seed crystal is promote to grow through controlling the temperature and time in these steps, and finally the required superconducting bulk is obtained. Through the above control, the precise control and stability of the growth process of the original REBCO seed crystal are realized. Through controlling the temperature and time appropriately, formation and growth of the crystal can be promoted, so as to obtain the superconducting bulk with good crystallization quality and performance. Besides, through controlling the cooling rate and temperature changes, inhomogeneity and deformation of crystal formation during the growth process can be avoided, so as to ensure that final superconducting bulk has excellent uniformity and stability.
(S3) Cleavage is performed on the original REBCO superconducting bulk along a preset cleavage plane to obtain a cleavage structure composed of the first buffer layer and the original REBCO seed crystal, and the cleavage structure is ground and polished to obtain a recycled seed crystal.

In this step, the seed crystal that utilizes the original REBCO superconducting bulk is effectively recycled to provide a high-quality seed crystal for subsequent growth process, which is conductive to the quality and uniformity of a newly grown superconductor material. The method of the present disclosure is based on a top seeded melt growth (TSMG) method, and it is needed to carefully study the crystal orientation and adopt an appropriate method to precisely cleave a seed crystal-buffer layer structure during cleavage process, and then the cleavage plane of the cleavage structure composed of the first buffer layer and the original REBCO seed crystal is subjected to polishing to ensure that the recycled seed crystal has a natural crystal orientation at each recycling time, which can correctly guide the texture growth of the precursor during the growth process. Step (S3) includes steps (S31)-(S32).
(S31) Cleavage is performed on the original REBCO superconducting bulk along a crystal ab plane through a cutting tool to obtain REBCO bulk seed crystal with the first buffer layer with a thickness of 0.5 mm, where the crystal ab plane is a layering cross section of a layered structure in the original REBCO superconducting bulk.
(S32) The cleavage plane of the REBCO bulk seed crystal is polished through a 1000-mesh sandpaper to obtain the recycled seed crystal.

It can be understood that in this step, the original REBCO superconducting bulk is cleaved along the ab plane of the crystal, that is, the layered cross section of a layering structure of the crystal, so as to obtain the REBCO bulk seed crystal with the first buffer layer with a thickness of 0.5 mm. This step is to separate a bulk seed crystal with a buffer layer with a certain thickness from the original bulk for subsequent continuous recycling. It can be understood that the original REBCO superconducting bulk can be effectively separated and processed through this step, so as to obtain the bulk seed crystal with a buffer layer with a certain thickness, and its cleavage plane is subjected to smooth and uniform treatment. Such treatment can ensure that the recycled seed crystal has good surface quality and morphology, and can effectively participate in the subsequent growth process, so as to achieves effective continuous recycling of the REBCO bulk seed crystal.
(S4) A second precursor and a second buffer layer are prepared. The recycled seed crystal is placed on a center of a top of the second precursor. the second buffer layer is coaxially inserted between the recycled seed crystal and the second precursor to obtain a precursor assembly, where a weight ratio of powders for preparing the second buffer layer to powders for preparing the first buffer layer is 1:2.

It can be understood that this step provides an ideal substrate and base for subsequent step of superconductor growth. Meanwhile, the recycled seed crystal is utilized to reduce production cost and improve efficiency of resource utilization.
(S5) Based on the top-seeded melt-texture growth method, the heating treatment is performed on the precursor assembly to obtain a REBCO superconducting bulk grown from the recycled seed crystal.

It can be understood that in this step, a rare earth element in the REBCO bulk seed crystal is selected the group consisting of from yttrium (Y), gadolinium (Gd), samarium (Sm) and neodymium (Nd). The method of the present disclosure further includes steps (S6)-(S7) after step (S5).
(S6) A seed crystal is recycled from the REBCO superconducting bulk grown from the recycled seed crystal, and grinding and polishing are performed on the REBCO superconducting bulk grown from the recycled seed crystal and the original REBCO superconducting bulk to obtain two completely-grown bulks. Annealing is performed on the two completely-grown bulks in the furnace at a flowing oxygen atmosphere at 450° C. for 200 h to obtain two annealed REBCO superconducting bulks.
(S7) A magnetic levitation force test is performed on the two annealed REBCO superconducting bulks to obtain a test result.

It can be understood that in this step, bulks are placed in the furnace for annealing at the flowing oxygen atmosphere at 450° C. for 200 h. The annealing is to achieve the transformation of the crystal structure of the bulks to obtain superconductivity, so as to improve superconductivity and stability of the bulks. The magnetic levitation force test is to accurately evaluate the superconducting performance of the bulks, so as to ensure that the bulks meet design requirements, and determine changes in magnetic levitation force of the bulks. Referring to FIG. 2, the original REBCO superconducting bulk and the REBCO superconducting bulk grown from the recycled seed crystal have highly consistent magnetic levitation performance, therefore, the present disclosure can repeatedly prepare REBCO superconducting bulks from growth morphology and magnetic levitation force performance.

Described above are merely preferred embodiments of the present disclosure, which are not intended to limit the disclosure. For those of ordinary skill in the art, various modifications, variations and replacements can be made to the technical features recited in the above embodiments. It should be understood that any modifications, replacements and variations made without departing from the spirit of the present disclosure shall fall within the scope of this application defined by the appended claims.

What is claimed is:

1. A method for recycling rare-earth barium copper oxide (REBCO) bulk seed crystals to grow a superconducting bulk, comprising:
(S1) preparing a first precursor and a first buffer layer based on a preset REBCO superconducting bulk precursor preparation method and a preset REBCO superconducting bulk buffer layer preparation method;
(S2) based on a top-seeded melt-texture growth method, performing a heating treatment on an original REBCO seed crystal, the first precursor and the first buffer layer to obtain an original REBCO superconducting bulk;
(S3) performing cleavage on the original REBCO superconducting bulk along a preset cleavage plane to obtain a cleavage structure composed of the first buffer layer and the original REBCO seed crystal, and grinding and polishing the cleavage structure to obtain a recycled seed crystal;
(S4) preparing a second precursor and a second buffer layer; placing the recycled seed crystal on a center of a top of the second precursor; and coaxially inserting the second buffer layer between the recycled seed crystal and the second precursor to obtain a precursor assembly; and
(S5) based on the top-seeded melt-texture growth method, performing the heating treatment on the precursor assembly to obtain a REBCO superconducting bulk grown from the recycled seed crystal;
wherein step (S2) comprises:
inserting the first buffer layer between the original REBCO seed crystal and the first precursor to form a composite structure, wherein the original REBCO seed crystal, the first buffer layer and the first precursor are coaxial from top to bottom; and
placing the composite structure on an aluminum oxide ceramic plate, followed by transfer to a furnace in an air atmosphere for texture growth to obtain the original REBCO superconducting bulk induced by the original REBCO seed crystal;
wherein the step of inserting the first buffer layer between the original REBCO seed crystal and the first precursor to form a composite structure comprises:
selecting a single REBCO seed crystal grain with a smooth cross section and a size of 3 mm×3 mm×3 mm as the original REBCO seed crystal; and polishing ab plane of the original REBCO seed crystal; and
placing the original REBCO seed crystal between the first buffer layer and the first precursor with a central axis of the original REBCO seed crystal perpendicular to ground aligned with a central axis of the first buffer layer and a central axis of the first precursor, so as to obtain the composite structure; and
the step of performing cleavage on the original REBCO superconducting bulk along the preset cleavage plane comprises:
performing cleavage on the original REBCO superconducting bulk along a crystal ab plane through a cutting tool to obtain a REBCO bulk seed crystal with the first buffer layer with a thickness of 0.5 mm, wherein the crystal ab plane is a layering cross section of a layered structure in the original REBCO superconducting bulk; and
polishing a cleavage plane of the REBCO bulk seed crystal through a 1000-mesh sandpaper to obtain the recycled seed crystal.

2. The method of claim 1, wherein step (S1) comprises:
mixing RE₂O₃, BaCO₃ and CuO in a molar ratio of 1:4:6 to obtain an original RE123 powder; and mixing RE₂O₃, BaCO₃ and CuO in a molar ratio of 1:1:1 to obtain an original RE211 powder;
performing solid-phase sintering on the original RE123 powder and the original RE211 powder to obtain a purified RE123 powder and a purified RE211 powder, respectively;
mixing the purified RE123 powder and the purified RE211 powder in a molar ratio of 1:0.35 to obtain a precursor powder; and mixing the precursor powder with a CeO₂ powder to obtain a precursor pellet, wherein the CeO₂ powder is 1% by weight of the precursor powder;
pressing the precursor pellet in a first mold to obtain the first precursor; and
pressing the purified RE123 powder, the purified RE211 powder and the CeO₂ powder in a preset ratio in a second mold to obtain the first buffer layer.

3. The method of claim 2, wherein the step of performing solid-phase sintering on the original RE123 powder and the original RE211 powder comprises:
sintering the original RE123 powder at 920° C. in an air atmosphere for 48 h to obtain a sintered RE123 powder, and sintering the original RE211 powder at 930° C. in an air atmosphere for 48 h to obtain a sintered RE211 powder; and
performing grinding and sintering on the sintered RE123 powder three times to obtain the purified RE123 powder, and performing grinding and sintering on the sintered RE211 powder three times to obtain the purified RE211 powder.

4. The method of claim 2, wherein the step of pressing the purified RE123 powder, the purified RE211 powder and the CeO₂ powder in the preset ratio in the second mold to obtain the first buffer layer comprises:
mixing the purified RE123 powder and the purified RE211 powder in a molar ratio of 5:2, followed by mixing with the CeO₂ powder to obtain a second mixed powder, wherein the CeO₂ powder is 1% by weight of a mixture of the purified RE123 powder and the purified RE211 powder; and
placing the second mixed powder in the second mold followed by pressing to obtain the first buffer layer with a cylindrical shape, wherein the second mold is a cylindrical mold with a diameter of 6 mm.

5. The method of claim 1, wherein the step of placing the composite structure on the aluminum oxide ceramic plate, followed by transfer to the furnace in the air atmosphere for texture growth comprises:
heating the furnace for 1 h to allow a temperature in the furnace to increase from room temperature to 900° C., keeping the furnace at 900° C. for 3 h, heating the furnace for 1 h to allow the temperature to increase from 900° C. to 1055° C., and keeping the furnace at 1055° C. for 1 h;
cooling the furnace to 1005° C. within 30 min; and cooling the furnace at a cooling rate of 0.2K/h-0.4K/h to allow the original REBCO seed crystal to induce the texture growth of the first precursor for 100 h; and
after the texture growth, cooling the furnace to the room temperature within 3 h.

6. The method of claim 1, wherein a rare earth element in the REBCO bulk seed crystal is selected from the group consisting of yttrium (Y), gadolinium (Gd), samarium (Sm) and neodymium (Nd).

7. The method of claim 1, after obtaining the REBCO superconducting bulk grown from the recycled seed crystal, further comprising:
recycling a seed crystal from the REBCO superconducting bulk grown from the recycled seed crystal, and performing grinding and polishing on the REBCO superconducting bulk grown from the recycled seed crystal and the original REBCO superconducting bulk to obtain two completely-grown bulks;
annealing the two completely-grown bulks in the furnace in a flowing oxygen atmosphere at 450° C. for 200 h to obtain two annealed REBCO superconducting bulks; and
performing a magnetic levitation force test on the two annealed REBCO superconducting bulks to obtain test results.
